(19) United States
(12) Patent Application Publication
(10) Pub. No.: US 2024/0055277 A1
(43) Pub. Date: Feb. 15, 2024

(54) SUBSTRATE PROCESSING APPARATUS AND SUBSTRATE PROCESSING METHOD

(71) Applicant: SCREEN Holdings Co., Ltd., Kyoto (JP)

(72) Inventors: Noritake SUMI, Kyoto (JP); Masayuki ORISAKA, Kyoto (JP)

(21) Appl. No.: 18/259,253

(22) PCT Filed: Dec. 22, 2021
(86) PCT No.: PCT/JP2021/047508

§ 371 Date: Jun. 23, 2023

(30) Foreign Application Priority Data
Dec. 28, 2020 (JP) 2020-218386

(51) Int. Cl. H01L 21/67

(52) U.S. Cl. CPC H01L 21/6704; H01L 21/67248; H01L 21/67109; H01L 21/67253

(57) ABSTRACT

In a substrate processing apparatus and a substrate processing method for processing a substrate by a processing fluid in a supercritical state in a processing space in a chamber, a heater for heating inside of the chamber below the substrate is arranged in the chamber, the substrate is carried into the processing space and heating by the heater is performed, the process fluid is supplied into the processing space and discharged from the processing space after the processing space is filled with the processing fluid in the supercritical state. The heating is stopped for a predetermined period from a time of introducing the processing fluid in the supercritical state into the processing space. While keeping inside the chamber a temperature suitable for a super-critical process, a temperature change causing a turbulence can be suppressed and the super-critical process to the substrate can be performed properly.

### TECHNICAL FIELD

This invention relates to a substrate processing apparatus and a substrate processing method for processing a substrate in a chamber using a processing fluid.

### BACKGROUND ART

The process of processing various substrates such as a semiconductor substrate and a glass substrate for a display apparatus includes processing the surface of the substrate with various processing fluids. Although processing using liquids such as chemicals and rinses as the processing fluids has been widely performed in the past, processing using supercritical fluids has been put into practical use in recent years. In particular, in the processing of a substrate having a fine pattern formed on its surface, a supercritical fluid having a lower surface tension than a liquid penetrates deep into gaps among the pattern, whereby the processing may be performed efficiently. In addition, the risk of pattern collapse due to the surface tension may be reduced in a drying process.

For example, PTL 1 describes a substrate processing apparatus that performs drying processing on a substrate using a supercritical fluid. In this apparatus, a processing chamber has a construction in which two plate-shaped members are disposed to face each other and the gap therebetween serves as a processing space. Then, the wafer (substrate) placed on a thin plate-shaped holding plate is carried in from one end part of the processing space, and carbon dioxide in the supercritical state is introduced from the other end part.

In this conventional technique, heaters are mounted on upper and lower wall surfaces of a chamber. The temperature of the chamber is maintained to be constant, e.g. at a temperature higher than a critical temperature of a processing fluid by the heating of the heaters. By doing so, the processing fluid introduced into the chamber can be converted into a supercritical state and that state can be stably maintained.

### CITATION LIST

### Patent Literature

PTL 1: JP2018-082043A (FIG. 3 for example)

### SUMMARY OF INVENTION

### Technical Problem

In the above conventional technique, how the process fluid flows in the chamber is not described in detail. However, according to knowledge of the inventors of the present invention, a flow of the process fluid in the chamber affects a quality of the process, that is, a cleanliness of the substrate after processing. Specifically, if there is a disturbance in the flow, for example, residual liquid separated from the substrate by the substitution action of the supercritical fluid may contaminate the substrate due to re-adhesion to the substrate.

Such a turbulence can be also generated by the temperature unevenness of the processing fluid in the chamber. This is because a convection is easily generated by temperature unevenness since a density of the fluid in the supercritical state largely varies with respect to temperature. From this, particularly a part inside the chamber to be directly contacted by the processing fluid desirably does not serve as such a heating source as to cause temperature unevenness in the processing fluid. However, the entire chamber having a large heat capacity is heated in the conventional technique, wherefore such a fine temperature control request could not be met.

As just described, in the chamber for a supercritical process, it is desired to maintain the inside of the chamber at a temperature suitable for the supercritical process, whereas a temperature change to cause a turbulence in the processing fluid in the supercritical state has to be avoided. These are contradictory requests.

### Solution to Problem

This invention was developed in view of the above problem and an object thereof is, in a substrate processing technique for processing a substrate by a processing fluid in a chamber, to provide a technique capable of satisfactorily performing a supercritical process for the substrate by suppressing a temperature change of the processing fluid causing a turbulence while maintaining the inside of the chamber at a temperature suitable for the supercritical process.

One aspect of this invention is directed to a substrate processing apparatus for processing a substrate by a processing fluid in a supercritical state and, to achieve the above object, the substrate processing apparatus including a chamber having a processing space capable of accommodating the substrate inside, a supply/discharge part for supplying the processing fluid into the processing space and discharging the processing fluid from the processing space, a heater arranged below the substrate in the chamber to heat inside of the chamber and a controller for controlling the heater, the controller stopping heating by the heater for a predetermined period from a time of introducing the processing fluid in the supercritical state into the processing space.

Another aspect of this invention is directed to a substrate processing method for processing a substrate by a processing fluid in a supercritical state in a processing space in a chamber and, to achieve the above object, the substrate processing method including arranging a heater for heating inside of the chamber below the substrate in the chamber, carrying the substrate into the processing space and performing heating by the heater, supplying the processing fluid into the processing space and discharging the processing fluid from the processing space after a state that the processing space is filled with the processing fluid in the supercritical state, and stopping the heating for a predetermined period from a time of introducing the processing fluid in the supercritical state into the processing space.

In the invention thus configured, the inside of the chamber can be maintained at a temperature suitable for a supercritical process by arranging the heater in the chamber and performing the heating. On the other hand, the heating by the heater is stopped when the processing fluid in the supercritical state is introduced into the chamber. Thus, it is avoided that the introduced processing fluid is warmed by the heating from the heater. Particularly, if the heater is arranged below the substrate accommodated in the chamber, a convection generated by an upward flow of the processing fluid having a low density by being warmed below the substrate causes a turbulence. The generation of such a turbulence can be suppressed by stopping the heating of the heater.

The supercritical process is performed for the purpose of replacing, for example, a liquid adhering to the substrate by the processing fluid in the supercritical state and removing the liquid from the substrate. An action to suppress the turbulence to prevent the liquid separated from the substrate from adhering to the substrate again may be continued until the start to the completion of the replacement of the liquid by the processing fluid in the supercritical state. That is, a state where the heating of the heater is stopped may be continued at least for a predetermined time from the time of introducing the processing fluid into the chamber to a time at which the process is considered to be completed.

### Advantageous Effects of Invention

As described above, in the present invention, the inside of the chamber can be maintained at a temperature suitable for a supercritical process by the heater arranged below the substrate in the chamber and performing the heating. On the other hand, the heating by the heater is stopped when the process using the processing fluid in the supercritical state is performed. Therefore, it is prevented that the substrate is contaminated by occurrence of the convection of the processing fluid warmed in the chamber. Thus, the substrate can be processed well.

### BRIEF DESCRIPTION OF DRAWINGS

FIG. 1 is a drawing showing a substrate processing apparatus capable of implementing a substrate processing method according to the present invention.

FIG. 2 is a flow chart showing a summary of a process performed by the substrate processing apparatus.

FIG. 3 is a phase chart showing a phase change in the supercritical process.

FIG. 4 is a timing chart showing a state change of each part of the supercritical process.

FIG. 5A is a diagram schematically showing a flow of the processing fluid in the processing chamber.

FIG. 5B is a diagram schematically showing a flow of the processing fluid in the processing chamber.

FIG. 6A is a diagram showing another arrangement example of the heater.

FIG. 6B is a diagram showing another arrangement example of the heater.

### DESCRIPTION OF EMBODIMENTS

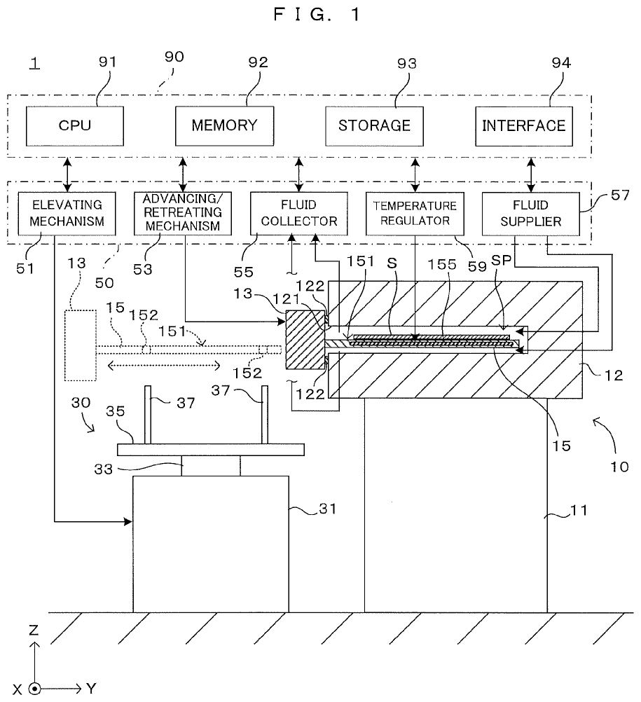

FIG. 1 is a drawing showing a schematic configuration of a substrate processing apparatus capable of implementing a substrate processing method according to the present invention. This substrate processing apparatus 1 is an apparatus for processing surfaces of various substrates such as semiconductor substrates using supercritical fluids. To show directions in each figure in a unified manner below, an XYZ orthogonal coordinate system is set as shown in FIG. 1. Here, an XY plane represents a horizontal plane and a Z direction represents a vertical direction. More specifically, a (−Z) direction represents a vertically downward direction.

Various substrates such as semiconductor wafers, glass substrates for photomask, glass substrates for liquid crystal display, glass substrates for plasma display, substrates for FED (Field Emission Display), substrates for optical disk, substrates for magnetic disk, and substrates for magneto-optical disk can be adopted as the “substrate” in this embodiment. A substrate processing apparatus used to process a disk-shaped semiconductor wafer is mainly described as an example with reference to the drawings. But the substrate processing apparatus can be adopted also to process various substrates illustrated above. Also as a shape of the substrate, various types are applicable.

The substrate processing apparatus 1 includes a processing unit 10, a transfer unit 30, a supply unit 50 and a control unit 90. The processing unit 10 serves as an execution subject of a supercritical drying process. The transfer unit 30 receives an unprocessed substrate S transported by an external conveying device not shown in the figure and carries the substrate S into the processing unit 10. Further, the transfer unit 30 delivers a processed substrate S from the processing unit 10 to the external conveying device. The supply unit 50 supplies chemical substances, power, energy and the like necessary for the process to the processing unit 10 and the transfer unit 30.

The control unit 90 realizes a predetermined process by controlling these components of the apparatus. For this purpose, the control unit 90 includes a CPU 91, a memory 92, a storage 93, an interface 94, and the like. The CPU 91 executes various control programs. The memory 92 temporarily stores processing data. The storage 93 stores the control programs to be executed by the CPU 91. The interface 94 exchanges information with a user and an external apparatus. Operations of the apparatus to be described later are realized by the CPU 91 causing each component of the apparatus to perform a predetermined operation by executing the control program written in the storage 93 in advance.

The processing unit 10 has a structure in which a processing chamber 12 is settled on a pedestal 11. The processing chamber 12 is structured by a combination of several metal blocks which form a hollow inside serving as a processing space SP. A substrate S to be processed is carried into the processing space SP to be processed. A slit-like aperture 121 elongated in an X direction is formed in a (−Y) side surface of the processing chamber 12. The processing space SP communicates with an outside space via the aperture 121. That is, the processing SP is a hollow having a cross-sectional shape that is long in the X direction and short in the Z direction and elongated in the Y direction.

A lid member 13 is provided on the (−Y) side surface of the processing chamber 12 to close the aperture 121. A hermetic processing chamber is constructed by closing the aperture 121 of the processing chamber when the aperture 121 is closed by the lid member 13. By doing so, a processing to the substrate S under a high pressure in the internal processing space SP is allowed. A support tray 15 in the form of a flat plate is attached in a horizontal posture to a (+Y) side surface of the lid member 13. An upper surface 151 of the support tray 15 serves as a support surface on which the substrate S can be placed. The lid member 13 is supported horizontally movably in a Y direction by an unillustrated support mechanism.

The lid member 13 is movable toward and away from the processing chamber 12 by an advancing/retreating mechanism 53 provided in the supply unit 50. Specifically, the advancing/retreating mechanism 53 includes a linear motion mechanism such as a linear motor, a linear guide, a ball-screw mechanism, a solenoid or an air cylinder. Such a linear motion mechanism moves the lid member 13 in the Y direction. The advancing/retreating mechanism 53 operates in response to a control command from the control unit 90.

By a movement of the lid member 13 in a (−Y) direction, the lid member 13 separates away from the processing chamber 12. If the support tray 15 is pulled out from the processing space SP to outside via the aperture 121 as shown by the dotted lines, the support tray 15 is accessible from outside. Specifically, it becomes possible to place the substrate S on the support tray 15 and take out the substrate S placed on the support tray 15. On the other hand, the lid member 13 moves in a (+Y) direction, whereby the support tray 15 is accommodated into the processing space SP. If the substrate S is placed on the support tray 15, the substrate S is carried into the processing space SP together with the support tray 15.

The lid member 13 moves in the (+Y) direction to close the aperture 121, whereby the processing space SP is sealed. A sealing member 122 is provided between the (+Y) side surface of the lid member 13 and the (−Y) side surface of the processing chamber 12 and an airtight state of the processing space SP is maintained. The seal member 12 is made of rubber material, for example. Further, the lid member 13 is fixed to the processing chamber 12 by an unillustrated lock mechanism. As described above, in this embodiment, the lid member 13 is switched between a closing state (solid line) to close the aperture 121 and seal the processing space SP and a separating state (dotted line) to enable the substrate S to pass through by separating widely from the aperture 121.

The substrate S is processed in the processing space SP with the airtight state of the processing space SP ensured in this way. In this embodiment, a fluid of a substance usable for a supercritical process, e.g. carbon dioxide, is sent from a fluid supplier 57 provided in the supply unit 50 as the processing fluid. The processing fluid is supplied to the processing unit 10 in a gaseous, liquid or supercritical state. Carbon dioxide is a chemical substance suitable for the supercritical drying process in having properties of entering a supercritical state at relatively low temperature and low pressure and dissolving an organic solvent often used in substrate processing well. At a critical point of carbon dioxide at which the fluid comes into the supercritical state, a pressure (critical pressure) is 7.38 MPa and a temperature (critical temperature) is 31.1° C.

The processing fluid is filled into the processing space SP. When suitable temperature and pressure are reached in the processing space SP, the processing space SP is filled with the processing fluid in the supercritical state. In this way, the substrate S is processed by the supercritical fluid in the processing chamber 12. The supply unit 50 is provided with a fluid collector 55, and the fluid after the process is collected into the fluid collector 55. The fluid supplier 57 and the fluid collector 55 are controlled by the control unit 90.

To prevent the processing fluid in the supercritical state from being cooled in the processing chamber 12 to undergo a phase change, an appropriate heat source is preferably provided inside the processing chamber SP. Particularly, to prevent an unintended phase change around the substrate S, a heater 155 is built in the support tray 15 in this embodiment. The heater 155 is temperature-controlled by a temperature regulator 59 of the supply unit 50.

The temperature regulator 59 operates in response to a control command from the control unit 90 and causes the heater 155 to generate heat by supplying power. The heater 155 generates heat to heat the support tray 15, and the inner wall surface of the processing space SP is warmed by radiant heat from the support tray 15. The temperature regulator 59 further has a function of controlling the temperature of the processing fluid supplied from the fluid supplier 57.

The processing space SP has a shape and a volume capable of receiving the support tray 15 and the substrate S supported by the support tray 15. That is, the processing space SP has a substantially rectangular cross-sectional shape wider than a width of the support tray 15 in a horizontal direction and larger than the sum of heights of the support tray 15 and the substrate S in the vertical direction and has a depth capable of receiving the support tray 15. As just described, the processing space SP has a shape and a volume enough to receive the support tray 15 and the substrate S. However, gaps between the support tray 15 and the substrate S and the inner wall surface of the processing space SP are tiny. Therefore, the amount of the processing fluid necessary to fill the processing space SP is relatively small.

With the support tray 15 accommodated in the processing space SP, the processing space SP is largely divided into two, i.e. spaces above and below the support tray 15. If the substrate S is placed on the support tray 15, the processing space SP is divided into a space above the upper surface of the substrate S and a space below the lower surface of the support tray 15.

The fluid supplier 57 supplies the processing fluid to each of the space above the substrate S and the space below the support tray 15, out of the processing space SP, on a (+Y) side further than a (+Y) side end part of the substrate S. On the other hand, the fluid collector 55 discharges the processing fluid from each of the space above the substrate S and the space below the support tray 15, out of the processing space SP, on a (−Y) side further than a (−Y) side end part of the substrate S. In this way, laminar flows of the processing fluid from the (+Y) side toward the (−Y) side are respectively formed above the substrate S and below the support tray 15 in the processing space SP.

The transfer unit 30 transfers the substrate S between an external conveying device and the support tray 15. To this end, the transfer unit 30 is provided with a body 31, an elevating member 33, a base member 35 and a plurality of lift pins 37. The elevating member 33 is a columnar member extending in the Z direction, and supported movably in the Z direction with respect to the body 31 by an unillustrated supporting mechanism. The base member 35 having a substantially horizontal upper surface is mounted atop the elevating member 33. The plurality of lift pins 37 stand upward from the upper surface of the base member 35. Each of the lift pins 37 supports the substrate S in a horizontal posture from below by the contact of an upper end part thereof with the lower surface of the substrate S. To stably support the substrate S in the horizontal posture, it is desirable to provide three or more lift pins 37 having the upper end parts located at the same height.

The elevating member 33 is movable up and down by an elevating mechanism 51 provided in the supply unit 50. Specifically, the elevating mechanism 51 includes a linear motion mechanism such as a linear motor, a linear motion guide, a ball screw mechanism, a solenoid or an air cylinder, and such a linear motion mechanism moves the elevating member 33 in the Z direction. The elevating mechanism 51 operates in response to a control command from the control unit 90.

The base member 35 is moved up and down by upward and downward movements of the elevating member 33, and the plurality of lift pins 37 are moved up and down integrally with the base member 35. In this way, the transfer of the substrate S between the transfer unit 30 and the support tray 15 is realized. More specifically, as shown by dotted lines in FIG. 1, the substrate S is transferred with the support tray 15 pulled out to the outside of the chamber. To this end, the support tray 15 is provided with through holes 152, through which the lift pins 37 are inserted. If the base member 35 moves up, the upper ends of the lift pins 37 reach positions above the upper surface 151 of the support tray 15 through the through holes 152. In this state, the substrate S being conveyed by the external conveying device is transferred to the lift pins 37. The lift pins 37 move down, whereby the substrate S is transferred from the lift pins 37 to the support tray 15. The substrate S can be carried out in a procedure opposite to the above one.

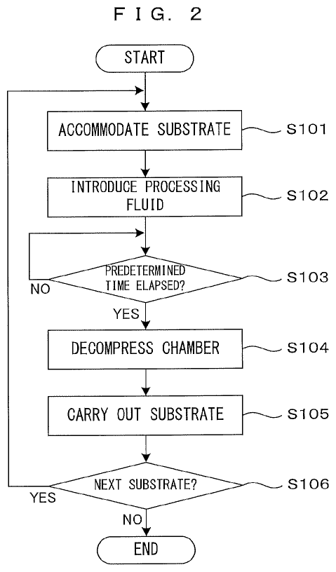

FIG. 2 is a flow chart showing a summary of a process performed by this substrate processing apparatus. This substrate processing apparatus 1 performs a supercritical drying process, i.e. a process of drying the substrate S cleaned with a cleaning liquid in a previous process. Specifically, this process is as follows. The substrate S to be processed is cleaned with the cleaning liquid in the previous process performed in another substrate processing apparatus constituting a substrate processing system. Thereafter, the substrate S is conveyed to the substrate processing apparatus 1 with a liquid film by an organic solvent such as isopropyl alcohol (IPA) formed on a surface.

For example, if a fine pattern is formed on the surface of the substrate S, the pattern may collapse due to surface tension of the liquid remaining on and adhering to the substrate S. Further, watermarks may remain on the surface of the substrate S due to incomplete drying. Further, the surface of the substrate S may be altered such as through oxidation by being exposed to outside air. To prevent such problems, the substrate S may be conveyed with the surface (pattern forming surface) of the substrate S covered by a liquid or solid surface layer.

For example, if the cleaning liquid contains water as a main component, conveyance is carried out with the liquid film formed by a liquid having a lower surface tension than the cleaning liquid and low corrosiveness to the substrate, e.g. an organic solvent such as IPA or acetone. That is, the substrate S is conveyed to the substrate processing apparatus 1 while being supported in a horizontal state and having the liquid film formed on the upper surface thereof. Here, it is assumed that IPA is used as an example of the liquid film material.

The substrate S conveyed by the unillustrated conveying device is accommodated into the processing chamber 12 (Step S101). Specifically, the substrate S is conveyed with the pattern forming surface serving as the upper surface and the upper surface covered by a thin liquid film. As shown by dotted lines in FIG. 1, the lift pins 37 move up with the lid member 13 moved to the (−Y) side and the support tray 15 pulled out. The conveying device transfers the substrate S to the lift pins 37. The lift pins 37 move down, whereby the substrate S is placed on the support tray 15. When the support tray 15 and the lid member 13 integrally move in the (+Y) direction, the support tray 15 supporting the substrate S is accommodated into the processing space SP in the processing chamber 12 and the opening 121 is closed by the lid member 13.

In this state, carbon dioxide serving the processing fluid is introduced in a gas phase state into the processing space SP (Step S102). Outside air enters the processing space SP when the substrate S is carried in, but it can be replaced by introducing the processing fluid in the gas phase. Further, by injecting the processing fluid in the gas phase, a pressure in the processing chamber 12 increases.

Note that, in the process of introducing the processing fluid, the processing fluid is continually discharged from the processing space SP. That is, the processing fluid is discharged from the processing space SP by the fluid collector 55 also while the processing fluid is being introduced by the fluid supplier 57. In this way, the processing fluid used for the process is discharged without convection in the processing space SP, thereby preventing impurities such as the remaining liquid taken into the processing fluid from adhering to the substrate S again.

If the supply amount of the processing fluid is more than the discharge amount, the density of the processing fluid in the processing space SP increases and the chamber internal pressure increases. Conversely, if the supply amount of the processing fluid is less than the discharge amount, the density of the processing fluid in the processing space SP decreases and the inside of the chamber is decompressed.

If the pressure of the processing fluid in the processing space SP increases and exceeds a critical pressure, the processing fluid enters a supercritical state in the chamber. That is, due to a phase change in the processing space SP, the processing fluid transitions from the gas phase to the supercritical state. Note that the processing fluid in the supercritical state may be supplied from outside. By maintaining a state, where the processing space SP is filled with the supercritical fluid, for a predetermined time (Step S103), the liquid component (IPA) adhering to the substrate S can be dissolved in the fluid and separated from the substrate S. This “predetermined time” is set in advance as a time necessary to reliably replace the liquid component adhering to the substrate S by the processing fluid and discharge the liquid component to the outside of the chamber. The liquid component separated from the substrate S is discharged, together with the processing fluid, to the outside of the chamber. In this way, the liquid component remaining on the substrate S is completely removed.

Subsequently, the substrate S is dried by discharging the processing fluid in the processing space SP. Specifically, by increasing a discharge amount of the fluid from the processing space SP, the inside of the processing chamber 12 filled with the processing fluid in the supercritical state is decompressed (Step S104). At this time, the supply of the processing fluid may be stopped or a small amount of the processing fluid may continue to be supplied. By decompressing the processing space SP from the state filled with the supercritical fluid, the processing fluid undergoes a phase change from the supercritical state to the gas phase. By discharging the vaporized processing fluid to outside, the substrate S is dried. At this time, a decompression speed is regulated so as not to create a solid phase and a liquid phase due to a sudden temperature drop. In this way, the processing fluid in the processing space SP is directly vaporized from the supercritical state and discharged to outside. Therefore, the formation of a gas-liquid interface on the substrate S having the exposed surface after drying is avoided.

As just described, in the supercritical drying process of this embodiment, the liquid adhering to the substrate S can be efficiently replaced and prevented from remaining on the substrate S by changing the phase of the processing fluid to the gas phase and discharging the processing fluid after the processing space SP is filled with the processing fluid in the supercritical state. Moreover, the substrate can be dried while avoiding problems caused due to the formation of the gas-liquid interface such as the contamination of the substrate by adhering impurities and pattern collapse.

The processed substrate S is delivered to a subsequent process (Step S105). That is, the lid member 13 moves in the (−Y) direction, whereby the support tray 15 is pulled out to outside from the processing chamber 12 and the substrate S is transferred to the external conveying device via the transfer unit 30. At this time, the substrate S is in the dried state. The content of the subsequent process is arbitrary. Unless there is a substrate to be processed next (NO in Step S106), the process is finished. If there is another substrate to be processed (YES in Step S106), return is made to Step S101, the substrate S is newly received and the above process is repeated.

If the next substrate S is successively processed after the process for one substrate S is finished, a tact time can be shortened as follows. That is, after the support tray 15 is pulled out and the processed substrate S is carried out, the support tray 15 is accommodated into the processing chamber 12 after a new unprocessed substrate S is placed thereon. Further, by reducing the number of opening and closing the lid member 13 in this way, an effect of suppressing a temperature change in the processing chamber 12 due to the entrance of outside air is also obtained.

For example, in the case of using a supercritical fluid for the purpose of replacing a liquid, the higher the density of the supercritical fluid, the higher the replacement efficiency. The density of the supercritical fluid is largely changed by temperature. Specifically, the higher the temperature, the lower the density. Therefore, a lower temperature is preferable to obtain the supercritical fluid having a high density. In this sense, a temperature near a critical temperature is desirable, but a phase transition to a gas or liquid phase is easily caused by a small temperature change. Thus, the temperature in the processing chamber 12 is desirably as constant as possible. Particularly, if the supercritical fluid is carbon dioxide, the critical temperature (about 31° C.) is close to a normal temperature, wherefore a temperature change due to the influence of outside air may impair the stability of the process.

To avoid this problem and stabilize the temperature in the processing chamber 12, the heater 155 for warming the inside of the processing chamber 12 is built in the support tray 15 in the substrate processing apparatus 1 of this embodiment. However, the temperature of the introduced processing fluid and the temperature of the support tray 15 are not perfectly equal, and the temperature of the processing fluid itself varies due to compression and expansion during the process. Further, a temperature change is also caused by the entrance of outside air every time the lid member 13 is opened and closed. Thus, it is not easy to keep the temperature in the processing chamber 12 constant. A temperature control in the processing chamber 12 in this embodiment is described below.

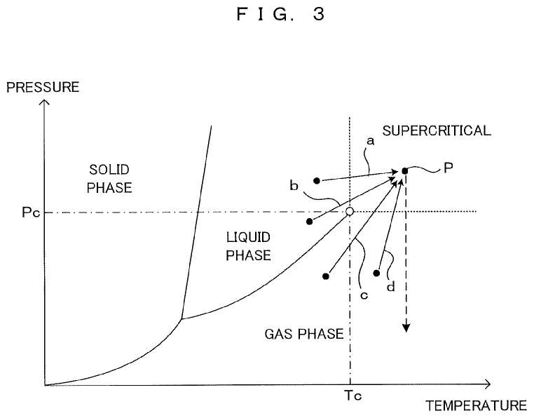

FIG. 3 is a phase chart showing a phase change in the supercritical process. In filling the chamber with the supercritical fluid to perform the supercritical process, the processing fluid set in the supercritical state in advance may be introduced into the processing chamber. However, it is realistic to introduce the processing fluid in the more easily handleable liquid or gas phase since the density of the supercritical fluid is largely changed by a temperature or pressure change as described above. That is, the processing fluid is introduced in the gas or liquid phase and the phase thereof is transitioned to the supercritical state in the chamber. In this case, as shown by arrows a to d in FIG. 3, various pressure and temperature changes of the processing fluid are considered.

In FIG. 3, a white circle symbol represents a critical point of carbon dioxide, which is the processing fluid of this embodiment. Reference signs Pc, Tc respectively denote a critical pressure and a critical temperature. Further, a point P represents a pressure and a temperature targeted in the supercritical process. From the perspective of processing efficiency, the point P is preferably close to the critical point (white circle symbol).

The arrows a, b correspond to a case where the processing fluid in the liquid phase is introduced. More specifically, the arrow a indicates a case where the processing fluid in a liquid state having a higher pressure than the critical pressure Pc and a lower temperature than the critical temperature Tc is caused to transition to the supercritical state by being heated in the chamber. Further, the arrow b indicates a case where the processing fluid in the liquid state having a lower pressure than the critical pressure Pc and a lower temperature than the critical temperature Tc is caused to transition to the supercritical state by being pressurized and heated in the chamber. In either case, the pressure and temperature are controlled not to cause the phase transition to the gas phase.

Further, the arrows c, d correspond to a case where the processing fluid in the gas phase is introduced. More specifically, the arrow c indicates a case where the processing fluid in a gas state having a lower pressure than the critical pressure Pc and a lower temperature than the critical temperature Tc is caused to transition to the supercritical state by being pressurized and heated in the chamber. Further, the arrow d indicates a case where the processing fluid in the gas state having a lower pressure than the critical pressure Pc and a higher temperature than the critical temperature Tc is caused to transition to the supercritical state by being pressurized in the chamber. In either case, the pressure and temperature are controlled not to cause the phase transition to the liquid phase.

By any of these modes, the introduced processing fluid can be brought to the supercritical state (point P) having a higher pressure than the critical pressure Pc and a higher temperature than the critical temperature Tc. On the other hand, when supercritical process is finished, the inside of the chamber is decompressed to change the phase of the processing fluid from the supercritical state to the gas phase as indicated by a broken-line arrow, whereby the substrate can be dried and taken out. By causing the phase of the processing fluid to transition from the supercritical state to the gas phase without passing through the liquid phase, the pattern collapse caused by the contact of a gas-liquid interface with the dried substrate surface is prevented.

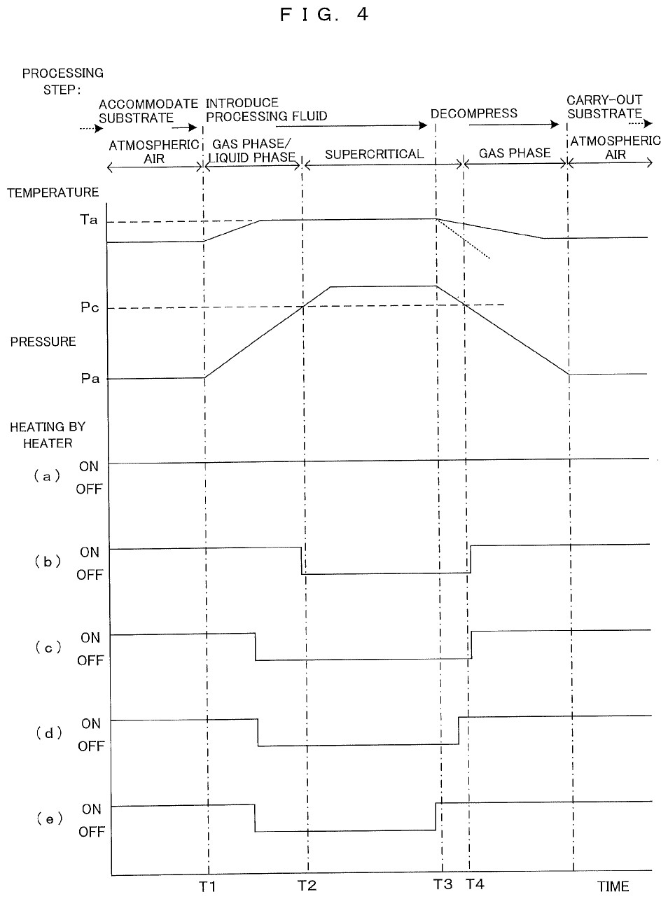

FIG. 4 is a timing chart showing a state change of each part of the supercritical process of this embodiment. As described above, the supercritical process of this embodiment includes processing steps of accommodating the substrate, introducing the processing fluid, decompressing the inside of the chamber and carrying out the substrate. If the supercritical process is performed successively for a plurality of substrates, a new unprocessed substrate is accommodated and the process is repeated after the processed substrate is carried out as indicated by dotted-line arrows.

During this time, the fluid in the processing chamber 12 changes in the order of the atmospheric air (open), the processing fluid in the gas or liquid phase, the processing fluid in the supercritical state, the processing fluid in the gas phase and the atmospheric air. Associated with this, the temperature and pressure in the processing chamber 12 also vary. In the case of using carbon dioxide as the processing fluid, a temperature change is relatively small in this process since the critical temperature Tc is relatively close to a normal temperature. For the temperature in the chamber, a temperature Ta in the supercritical state only has to be higher than the critical temperature Tc (FIG. 3) and the temperature in the chamber may be higher or lower than the critical temperature Tc during other periods.

On the other hand, the chamber internal pressure largely changes from an atmospheric pressure Pa to a pressure exceeding the critical pressure Pc. For a period during which both the temperature and the pressure in the chamber exceed the critical point, the inside of the chamber is filled with the processing fluid in the supercritical state. Since it is not very difficult to merely maintain the chamber internal temperature at a temperature higher than the critical temperature Tc, whether or not the fluid in the chamber enters the supercritical state is mainly determined by the pressure change. The pressure of the fluid in the chamber is determined by a supply and discharge balance of the processing fluid, i.e. a relationship between the supply amount of the processing fluid from the fluid supplier 57 and the discharge amount of the processing fluid to the fluid collector 55.

As just described, in the supercritical process, the chamber internal temperature needs not necessarily be varied, but a temperature suitable for the process is desirably maintained. In that sense, a temperature change is preferably small. For example, in extreme cases, the temperature may be always constant. Further, from the perspective of the safety of the process result in the continual process for the plurality of substrates, the temperature in the processing chamber 12 and the temperature of the support tray 15 in accommodating the substrate S are desirably the same every time.

The chamber internal temperature not only depends on the temperature of the fluid introduced into the chamber, but also is influenced by a temperature variation due to the expansion and contraction of the fluid in pressurizing and decompressing processes in the process. To reduce a temperature change due to these, the heater 155 built in the support tray 15 is used.

A configuration for providing a heater in or around a chamber to maintain the temperature in the chamber is known. That is, a technique for suppressing the influence of temperature changes of outside air and a fluid by heating a processing chamber having a large heat capacity and a support tray has been put to practical use. In that case, as shown by reference sign (a) in FIG. 4, the heater is thought to be constantly on to stabilize the temperature.

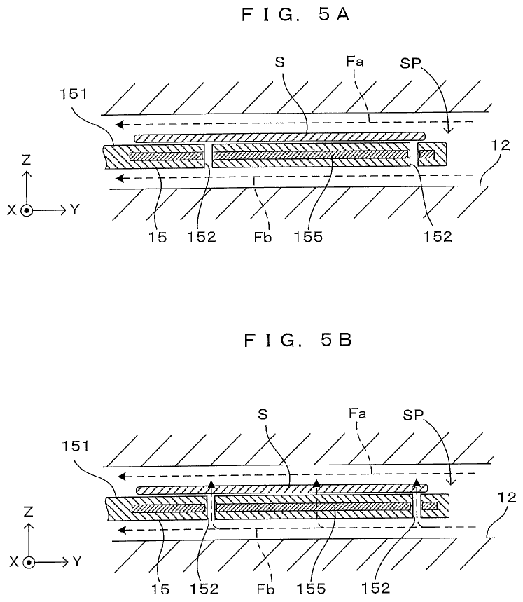

FIGS. 5A and 5B are diagrams schematically showing flows of the processing fluid in the processing chamber. As shown in FIG. 5A, laminar flows Fa, Fb of the supercritical processing fluid flowing from the (+Y) side to the (−Y) side are desirably formed above the substrate S and below the support tray 15 respectively in the processing space SP. However, if the temperature of the support tray 15 heated by the heater 155 is higher than the temperature of the processing fluid, particularly the temperature of the processing fluid flowing below the support tray 15 at this time, the processing fluid is warmed.

If the temperature of the supercritical fluid increases, the density thereof decreases and a convection of the processing fluid is generated in the processing space SP. That is, as shown in FIG. 5B, part of the processing fluid flowing below the support tray 15 flows around to a side above the substrate S through the gaps between the side wall surfaces of the processing chamber and the support tray 15, the through holes 152 provided in the support tray 15 and the like. If a turbulence is generated around the substrate S in this way, the remaining fluid replaced by the processing fluid and dissolved into the processing fluid may adhere to the substrate S again and contaminate the substrate S. To solve this problem, the heater 155 is turned off during the supercritical process to temporarily stop the heating of the support tray 15 by the heater 155 in this embodiment. In this way, the generation of a turbulence due to a temperature increase of the processing fluid by the heater 155 is avoided. The temperature of the support tray 15 after the heater is turned off approaches the temperature of the introduced processing fluid.

In principle, as shown by reference sign (b) in FIG. 4, the heater 155 may be turned off at least while the inside of the chamber is filled with the supercritical fluid, i.e. from time T2 to time T4. At a timing at which the phase of the processing fluid transitions to the supercritical state, the supercritical fluid and the liquid adhering to the substrate S coexist. A situation where the processing fluid is warmed to generate a turbulence at this time needs to be reliably avoided from the perspective of preventing the contamination of the substrate.

However, practically, it is difficult to precisely predict time T2 at which the phase of the introduced processing fluid transitions to the supercritical state in the chamber and, further, the heating of the heater is considered to influence that time. Accordingly, as shown by reference sign (c) in FIG. 4, the heater 155 is desirably turned off earlier than time T2 at which a phase transition would occur. For example, the heater 155 can be turned off at time T1 at which the introduction of the processing fluid is started. Further, for example, the heater 155 may be turned off immediately after the lid member 13 is closed.

On the other hand, a final stage of the heater turn-off, i.e. a timing at which the turned-off heater 155 is turned on again, can be considered as follows. A turned-off state of the heater 155 is preferably continued at least until the replacement of the liquid component by the supercritical fluid is completed on the substrate S, more strictly for a period until the liquid component separated from the substrate S is discharged from the processing space SP. When the liquid component remains in the processing fluid as in the initial stage of the supercritical process, a turbulence generated by a convection possibly causes the contamination of the substrate S. However, after the liquid component is discharged, the turbulence does not necessarily cause the contamination.

Thus, the heating of the heater may be resumed in a situation where the supercritical state is sufficiently continued and the liquid component does not remain around the substrate S. For example, as shown by reference sign (d) in FIG. 4, the heater 155 may be turned on earlier than time T4 at which the phase of the processing fluid in the chamber transitions from the supercritical state to the gas phase.

Particularly, if the heater 155 is turned on earlier than time T3 at which the decompression of the inside of the chamber is started as shown by reference sign (e) in FIG. 4, the following effect is obtained. In the phase transition from the supercritical state to the gas phase, the temperature in the chamber suddenly decreases as indicated by a dotted line in FIG. 4 due to the adiabatic expansion of the processing fluid associated with decompression and, depending on cases, this temperature may possibly become lower than an outside air temperature. Such a temperature drop contradicts the purpose of maintaining the chamber internal temperature constant. Particularly, a phase transition to the liquid phase due to a sudden decrease of the chamber internal temperature with a high pressure state kept has to be reliably avoided. By turning on the heater 155 before the start of decompression, such a temperature drop can be suppressed.

It is difficult to grasp at which point of time the replacement of the liquid component by the processing fluid was completed during the supercritical process. However, a timing at which the liquid component is no longer discharged from the processing space SP can be measured in advance, for example, by a preliminary experiment. The completion of the replacement can be estimated upon the elapse of a time corresponding to the measured timing. By turning on the heater 155 thereafter, effects similar to the above ones can be obtained.

Note that a method for stopping the heat generation of the heater 155 in the initial stage of the supercritical process does not require the complete stop of the operation of the heater 155. For example, by setting a heating target temperature of the heater 155 sufficiently lower than an ambient temperature, heat generation from the heater 155 can be substantially stopped. Further, if the heater 155 is stopped after the processing fluid is introduced, heat generation can be stopped by setting a target temperature lower than the temperature of the introduced processing fluid.

Further, as long as the support tray 15 has a lower temperature than the temperature of the processing fluid, energization to the heater 155 may be continued. By maintaining the temperature of the heater 155 built in the support tray 15 at a certain temperature, the temperature of the support tray 15 can be immediately increased when necessary.

If the temperature of the processing fluid introduced in the gas phase state is, for example, about 50° C., the heating target temperature by the heater 155 can be set at a temperature slightly lower than this temperature, e.g. about 40° C. However, there is no limitation to these temperatures.

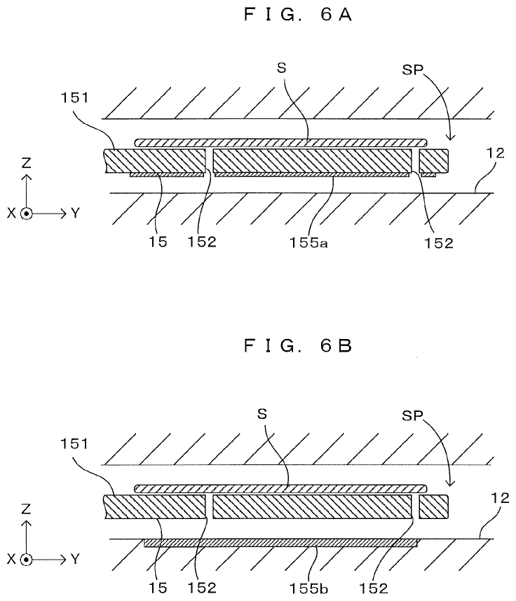

FIGS. 6A and 6B are diagrams showing other arrangement examples of heaters. The heater 155 of the above embodiment is embedded in the support tray 15 and heats the inside of the chamber via the support tray 15. On the other hand, in the example shown in FIG. 6A, a heater 155a is provided in a state exposed on the lower surface of the support tray 15. Also by such a configuration, the support tray 15 and the inside of the processing chamber 12 can be heated. Also in this case, a heater control similar to the above one is effective since a turbulence may be generated by the warming of the processing fluid flowing below by the heater 155a.

Note that it is not necessarily effective to provide the heater on the upper surface of the support tray 15. Even in such a configuration, it is possible to heat the support tray 15 and the inside of the processing chamber 12. However, when the substrate S is placed on the support tray 15, heat generated by the heater mainly warms the substrate S. This does not necessarily contribute to the stability of the process, for example, due to the evaporation of the liquid when the substrate S formed with the liquid film is placed on the support tray 15.

In the example shown in FIG. 6B, a heater 155b is provided in the processing chamber 12. More specifically, the heater 155b is provided at a position in the bottom surface of the processing space SP in the processing chamber 12. Also in this case, a heater control similar to the above one is effective since a turbulence is possibly generated by the heater 155b warming the processing fluid flowing between the heater 155b and the support tray 15.

Note that, in this configuration, a heating effect by the heater 155b is low for the support tray 15. Particularly, the support tray 15 is not heated when being pulled out to the outside of the chamber. On the other hand, in a configuration for arranging the heater in the support tray 15, the inside of the chamber is not heated when the support tray 15 is pulled out to the outside of the chamber. However, a temperature change is minor since the heat capacity of the processing chamber 12 is generally sufficiently larger than that of the support tray 15. Further, it is also possible to provide a separate heater on the side of the processing chamber 12. From these, it is rational to provide the heater in the support tray 15.

As described above, in the substrate processing apparatus 1 of the above embodiment, the processing chamber 12, the support tray 15 and the heater 155 (155a, 155b) respectively function as a “chamber”, a “support tray” and a “heater” of the invention. Further, the fluid supplier 57 and the fluid collector 55 integrally function as a “supply/discharge part” of the invention. The control unit 90 and the temperature regulator 59 integrally function as a “controller” of the invention. Further, in the above embodiment, carbon dioxide corresponds to a “processing fluid” of the invention and the organic solvent such as IPA for forming a liquid film on the carried-in substrate S corresponds to a “liquid to be replaced” of the invention.

Note that the invention is not limited to the above embodiment and various changes other than the aforementioned ones can be made without departing from the gist of the invention. For example, the substrate processing apparatus 1 of the above embodiment may be further provided with a heater provided on the outer surface of the processing chamber 12 or embedded in a housing block of the processing chamber 12. By warming the processing chamber in advance by such a heater, a temperature change in the processing space can be further reduced in a series of supercritical process steps. In this case, the temperature of the processing chamber is preferably set, for example, to about 30° C. so as not to be higher than the temperature of the processing fluid.

Further, for example, the heating target temperature when the heater is on is set to be constant in the sequence of the above embodiment, but the target temperature may be changed in multiple stages as necessary. For example, the target temperature may be different depending on whether the support tray 15 is in or outside the processing space SP. Further, in carrying out the processed substrate S to outside, the heating target temperature may be set to be lower than at other timings to promote the cooling of the substrate S.

Further, in the above embodiment, it is aimed to shorten a tact time by carrying in the next unprocessed substrate immediately after the processed substrate is carried out. However, also in a sequence of closing the lid member once after the substrate is carried out, a heater control similar to the above one is possible. That is, the heater may be turned on in opening and closing the lid member, and may be turned off before the supercritical state is reached in the chamber.

Further, various chemical substances used in the process of the above embodiment are only some examples. Various other chemical substances can be used instead of these if those chemical substances conform to the technical idea of the invention.

As the specific embodiment has been illustrated and described above, the substrate processing apparatus according to the invention may be configured such that the supply/discharge part discharges the processing fluid to dry the substrate after a state where the inside of the processing space is filled with the processing fluid in the supercritical state is continued for a predetermined time, and the controller stops heating at least for a period during which the processing space is filled with the processing fluid in the supercritical state. According to such a configuration, the temperature of the processing fluid can be prevented from being changed by heat generation of the heater over the entire period during which the processing space is filled with the processing fluid in the supercritical state.

Further, in a case that this substrate processing apparatus is for drying the substrate by replacing a liquid to be replaced adhering to the substrate by the processing fluid, the controller may be configured to stop heating until the replacement of the liquid to be replaced remaining in the processing space by the processing fluid is completed. A problem due to the heating of the processing fluid in the supercritical state is that a turbulence generated by heating causes contaminants to adhere to the substrate. In other words, if the heating by the heater is stopped until the replacement of the liquid to be replaced, which possibly becomes contaminants, is completed, the effects of the invention can be obtained.

Accordingly, for example, the controller may start heating after the replacement of the liquid to be replaced is completed. By doing so, a temperature drop after the process can be suppressed. In the process of drying the substrate from the supercritical state, the phase of the processing fluid desirably transitions to the gas phase without passing through the liquid phase. Heating by the heater can be utilized for the purpose of preventing a sudden temperature drop of the processing fluid and avoiding a phase transition to the liquid phase.

Further, for example, the supply/discharge part may dry the substrate by decompressing the processing space after the state where the inside of the processing space is filled with the processing fluid in the supercritical state is continued for a predetermined time, and the controller may start heating before the supply/discharge part starts to decompress the processing space. In this case, a temperature drop may be caused by sudden expansion of the processing fluid during decompression, but such a temperature drop can be suppressed by the heating of the heater.

Further, for example, in these substrate processing apparatuses, the supply/discharge part preferably supplies the processing fluid in the gas or liquid phase to the chamber, and the controller preferably stops heating before the phase of the processing fluid transitions to the supercritical state in the processing space. In such an initial stage of the supercritical process, substances serving as a contamination source of the substrate are thought to remain in the processing space. By stopping the heating of the heater and suppressing the generation of a turbulence of the processing fluid in such a stage, the adhesion of the remaining substances to the substrate can be prevented.

Further, for example, this substrate processing apparatus may be further provided with the support tray having a flat plate shape capable of placing the substrate on an upper part and configured to take the substrate into and out from the chamber by moving toward and away from the processing space, and the heater may be provided in the support tray. According to such a configuration, a temperature drop of the support tray can be prevented when the support tray is outside the chamber.

Further, for example, the controller may stop heating by the heater substantially by setting a heating target temperature by the heater to a temperature lower than a temperature of the processing fluid. That is, in this invention, it is sufficient to avoid a temperature rise of the processing fluid caused by heat generation of the heater, and it is not required to stop the operation of the heater itself

Further, in the substrate processing method according to this invention, heating may be continued until the carry-in of the unprocessed substrate is finished after the start of the carry-out of the processed substrate if the unprocessed substrate is newly carried into the chamber and the process using the processing fluid is performed after the processed substrate finished with the process using the processing fluid is carried out from the chamber. In the case of successively processing a plurality of the substrates in this way, a temperature drop in the chamber can be prevented by continuing heating by the heater while the substrates are exchanged.

### INDUSTRIAL APPLICABILITY

The present invention is applicable to every type of substrate processing apparatus that processes a substrate using a supercritical fluid introduced in a chamber. In particular, the present invention is preferably applicable to a substrate drying process of drying a substrate such as a semiconductor substrate with a supercritical fluid.

### REFERENCE SIGNS LIST

1 substrate processing apparatus
12 processing chamber (chamber)
15 support tray
55 fluid collector (supply/discharge part)
57 fluid supplier (supply/discharge part)
59 temperature regulator (controller)
90 control unit (controller)
155, 155a, 155b heater
S substrate
SP processing space

1. A substrate processing apparatus for processing a substrate by a processing fluid in a supercritical state, the substrate processing apparatus comprising:
a chamber which has a processing space capable of accommodating the substrate inside;
a supply/discharge part which supplies the processing fluid into the processing space and discharges the processing fluid from the processing space;
a heater which is arranged below the substrate in the chamber to heat inside of the chamber; and
a controller which controls the heater, wherein
the controller stops heating by the heater for a predetermined period from a time of introducing the processing fluid in the supercritical state into the processing space.

2. The substrate processing apparatus according to claim 1, wherein
the supply/discharge part discharges the processing fluid to dry the substrate after a state where the inside of the processing space is filled with the processing fluid in the supercritical state is continued for a predetermined time, and
the controller stops heating at least for a period during which the processing space is filled with the processing fluid in the supercritical state.

3. The substrate processing apparatus according to claim 1 which dries the substrate by replacing a liquid to be replaced adhering to the substrate by the processing fluid, wherein
the controller stops heating until replacement of the liquid to be replaced remaining in the processing space by the processing fluid is completed.

4. The substrate processing apparatus according to claim 3, wherein
the controller starts heating after the replacement of the liquid to be replaced is completed.

5. The substrate processing apparatus according to claim 1, wherein:
the supply/discharge part decompresses the processing space after continuing a state where the inside of the processing space is filled with the processing fluid in the supercritical state for a predetermined time, thereby dries the substrate; and
the controller starts heating before the supply/discharge part starts to decompress the processing space.

6. The substrate processing apparatus according to claim 1, wherein
the supply/discharge part supplies the processing fluid in a gas or liquid phase to the chamber, and
the controller stops heating before a phase of the processing fluid transitions to the supercritical state in the processing space.

7. The substrate processing apparatus according to claim 1,
further comprising a support tray which has a flat plate shape capable of placing the substrate on an upper part and takes the substrate into and out from the chamber by moving toward and away from the processing space, wherein
the heater is provided in the support tray.

8. The substrate processing apparatus according to claim 1, wherein
the controller stops heating by the heater substantially by setting a heating target temperature by the heater to a temperature lower than a temperature of the processing fluid.

9. A substrate processing method for processing a substrate by a processing fluid in a supercritical state in a processing space in a chamber, the substrate processing method comprising:
carrying the substrate into the processing space and performing heating inside of the chamber by a heater arranged below the substrate in the chamber;
supplying the processing fluid into the processing space and, after a state where the processing space is filled with the processing fluid in the supercritical state, discharging the processing fluid from the processing space; and
stopping the heating for a predetermined period from a time of introducing the processing fluid in the supercritical state into the processing space.

10. The substrate processing method according to claim 9, wherein:
after a processed substrate finished with a process using the processing fluid is carried out from the chamber, an unprocessed substrate is newly carried into the chamber and the process using the processing fluid is performed; and
the heating is continued until a carry-in of the unprocessed substrate is finished after a start of a carry-out of the processed substrate.
